(19) United States
(12) Patent Application Publication
(10) Pub. No.: US 2026/0299654 A1
(43) Pub. Date: Oct. 1, 2026

(54) AI LOW-VOLTAGE FUEL CELL POWER SYSTEM

(71) Applicant: MöbiVolt Defense LLC, Livermore, CA (US)

(72) Inventors: Ian W. KAYE, Livermore, CA (US); Ru CHEN, Dublin, CA (US); Jeff BALDIC, Milford, MA (US)

(21) Appl. No.: 19/633,593

(22) Filed: Mar. 30, 2026

Related U.S. Application Data
(60) Provisional application No. 63/779,898, filed on Mar. 28, 2025.
(60) Provisional application No. 63/851,129, filed on Jul. 25, 2025.

(51) Int. Cl. G06F 1/188; G06F 1/18; G06F 1/20; H01M 8/04701; H01M 8/04746; H01M 8/1004; H01M 8/18; H01M 50/264; H05K 7/20

(52) U.S. Cl. CPC G06F 1/188; G06F 1/189; G06F 1/206; H01M 8/04723; H01M 8/04746; H01M 8/1004; H01M 8/18; H01M 50/264; H05K 7/20772; H05K 7/20836

(57) ABSTRACT

A low-voltage fuel cell power system for directly powering a compute tray in a server rack in an artificial intelligence (AI) data center. The thin fuel cell power system can be mounted on the underside of a compute tray. A fuel cell assembly includes multiple fuel cell modules arranged in a single layer, with each fuel cell module electrically isolated from one another. A weak or failed fuel cell assembly can be swapped out without affecting other fuel cell assemblies in the server rack. The low-voltage fuel cell power system provides efficient, reliable energy to power AI data centers.

### RELATED APPLICATIONS

This application claims the benefit of U.S. Provisional Application No. 63/779,898, filed on Mar. 28, 2025, and U.S. Provisional Application No. 63/851,129, filed on Jul. 25, 2025. Each of the foregoing applications is hereby incorporated by reference herein for all purposes

### BACKGROUND OF THE INVENTION

The present disclosure generally relates to fuel cells. More specifically, the disclosure relates to fuel cell power systems for reliably powering a low voltage system suitable for artificial intelligence (AI) applications.

With the rapid rise of AI, data center power consumption has increased significantly in recent years. In 2023, data center power consumption in the United States was approximately 4.7% of total electricity usage, and is predicted to surge to 6.7%-12% by 2028. By 2035, data center power consumption may be 18% of U.S. power consumption. Large cloud data centers, also known as hyperscalers, use as much as 20 times the power used by a traditional data center. A typical AI data center consumes as much electricity as about 100,000 households. Data centers currently under development may consume up to 20 times more energy than current AI data centers.

Servers consume most of the power needed by AI data centers. Some of the need for energy is due to the need to cool the high-density servers for AI-focused computing. Due to the extreme heat generated by the servers, specialized cooling infrastructure, which typically requires massive amounts of energy, is employed to prevent overheating of the servers.

The electricity consumption of U.S. data centers was growing at a rate of about 7% from 2014 to 2018 and 18% from 2018 to 2023. It is predicted to increase to 13%-27% between 2023 and 2028. With this predicted growth in power consumption and concern for power grid stability, there is also an increased demand for energy efficient data centers and also alternative energy to power data centers. The increased demand for energy to power data centers will not be limited to the U.S. The rise of AI will lead to significant increases in global demand for power. Data centers currently consume about 1.5% of global electricity, and is projected to skyrocket to be as much as 20% of global electricity by 2030.

Dependence on the electrical grid to power AI data centers is unsustainable. Alternative energy and more energy efficient data centers will be necessary to meet the demand for energy needed for AI data centers. Fuel cells can be used in a wide range of power applications, including transportation, material handling, stationary, and portable power applications. Fuel cells are not only able to provide low-voltage power directly to graphics processing units (GPUs), but fuel cell power generation and delivery to AI data centers can also occur under the same roof within the data center itself, thereby reducing power losses due to transmission and conversion. Fuel cell power systems may be capable of providing cost effective, energy efficient, alternative power to meet the rapidly increasing power demand from AI data centers.

### SUMMARY OF THE INVENTION

In accordance with an embodiment, a low-voltage fuel cell power system is provided for directly powering a compute tray within a server rack system. The low-voltage fuel cell power system includes a fuel cell assembly electrically coupled to the compute tray to supply power to at least one graphics processing unit in the compute tray. The fuel cell assembly includes a plurality of fuel cell modules, which are electrically isolated from one another.

In accordance with another embodiment, a server rack is provided. The server rack includes at least one compute tray and a low-voltage power source. The compute tray includes at least one graphics processing unit (GPU). The low-voltage power source is electrically coupled to the at least one compute tray to power the at least one GPU.

In accordance with yet another embodiment, a low-voltage fuel cell power system is provided for directly powering a compute tray within a server rack system. The fuel cell power system includes a fuel cell assembly electrically coupled to the compute tray to supply power to at least one graphics processing unit in the compute tray. The fuel cell assembly includes a plurality of fuel cell modules arranged in a single layer. The fuel cell modules are electrically isolated from one another.

### BRIEF DESCRIPTION OF THE DRAWINGS

The invention, together with further objects and advantages thereof, may best be understood by reference to the following description taken in conjunction with the accompanying drawings in which:

FIG. 1 is a perspective view of the bottom of a fuel cell assembly in accordance with an embodiment.

FIG. 2 is a perspective view of the top of the fuel cell assembly shown in FIG. 1.

FIG. 3 is a detailed view of a portion of the bottom of the fuel cell assembly shown in FIG. 1.

FIG. 4 is detailed perspective view of the fuel cell assembly shown in FIGS. 1-3.

FIG. 5 is an exploded top perspective view of the fuel cell assembly shown in FIGS. 1-4.

FIG. 6 is an exploded top perspective view of a fuel cell module within a fuel cell assembly in accordance with an embodiment.

FIG. 7 is an exploded bottom perspective view of the fuel cell module shown in FIG. 6.

FIG. 8 is an exploded top perspective view of a fuel cell and compute tray power assembly in accordance with an embodiment.

FIG. 9 is an exploded bottom perspective view of the fuel cell and compute tray power assembly shown in FIG. 8.

FIG. 10 is an exploded top perspective view of a fuel cell power system in accordance with an embodiment.

FIG. 11 is an exploded bottom perspective view of the fuel cell power system shown in FIG. 10.

FIG. 12 is a top perspective view of the fuel cell power system shown in FIGS. 10 and 11.

FIG. 13 is a bottom perspective view of the fuel cell power system shown in FIGS. 10-12.

FIG. 14 is a server rack system holding multiple compute trays and fuel cell assemblies.

FIG. 15 is a schematic diagram of a low-voltage fuel cell power system powering a compute tray in accordance with an embodiment.

FIG. 16 is a schematic diagram of a low-voltage flow battery system in accordance with an embodiment.

FIG. 17 shows a performance curve of a representative fuel cell.

### DETAILED DESCRIPTION OF THE PREFERRED EMBODIMENTS

The present invention relates generally to fuel cell power systems for providing low-voltage power directly to GPUs. A typical server rack in an AI data center holds multiple individual compute trays containing GPUs. The GPUs require significant power. Embodiments of low-voltage fuel cell power systems described herein can generate low-voltage power and deliver the power directly to compute trays to which the fuel cell systems are connected. The thin, low profile fuel cell power systems provide direct energy to the compute trays in a server rack using an alternative fuel, such as hydrogen, thereby eliminating the need for electricity from the power grid. If one fuel cell power system in the sever rack needs to be replaced, that particular fuel cell power system can be easily swapped for a new one without causing the entire rack to shut down and stop functioning completely.

According to embodiments described herein, a low-profile, single-layer fuel cell assembly 100 comprises a plurality of independent, electrically isolated fuel cell modules 110 (e.g. 32 units) arranged in a planar matrix. The fuel cell assembly 100 integrates structural compression, fluidic distribution, and electrical termination into a multi-layered laminated architecture. According to an embodiment, the fuel cell assembly 100 with an encapsulating enclosure 102 has a total thickness that is less than 0.75 inch. This thin design allows the fuel cell assembly 100 to be attached directly to a compute tray that the fuel cell assembly powers in a server rack.

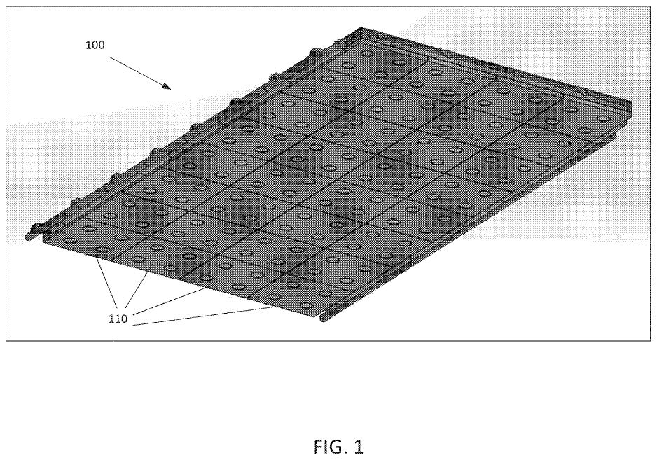

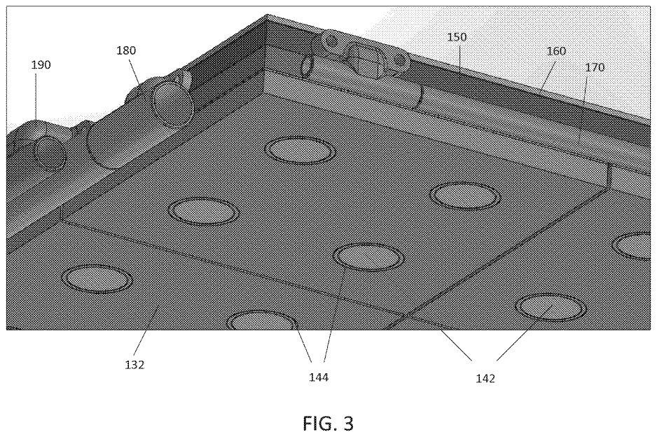

In the embodiment shown in FIG. 1, the fuel cell assembly 100 has 32 individually electrically isolated fuel cell modules 110 physically arranged in a single layer. The fuel cell modules 110 can be polymer electrolyte membrane (PEM) fuel cells having a membrane electrode assembly (MEA). As shown in the detailed view of FIG. 3, each fuel cell module 110 has ground terminals 132 and positive terminals 142. Electrical isolation allows the cells to be stacked electrically or used individually. In this embodiment, electrical isolation between the 32 modules allows for versatile electrical combinations in series, parallel, or hybrid configurations to meet specific voltage/current requirements. In one embodiment, the fuel cell assembly 100 is 34″×16″.

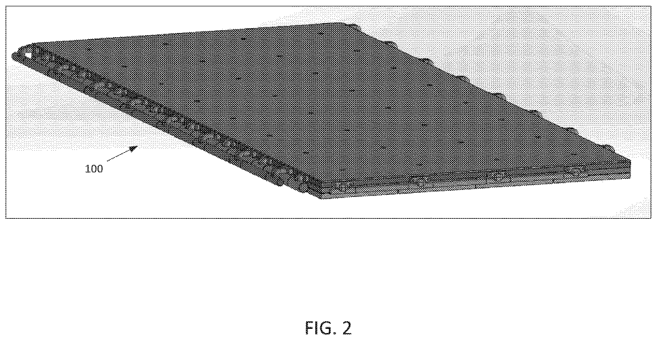

FIG. 2 is a top perspective view of the fuel cell assembly 100. As shown in FIG. 2, there are no electrical or fluidic connections on the top side of the fuel cell assembly 100. It will be understood that the top face of the fuel cell assembly 100 does not contact a PCB 104. The bottom face of the fuel cell assembly 100 contacts the PCB 104.

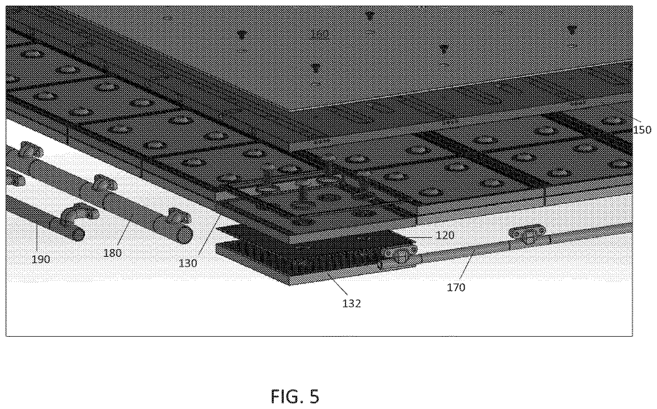

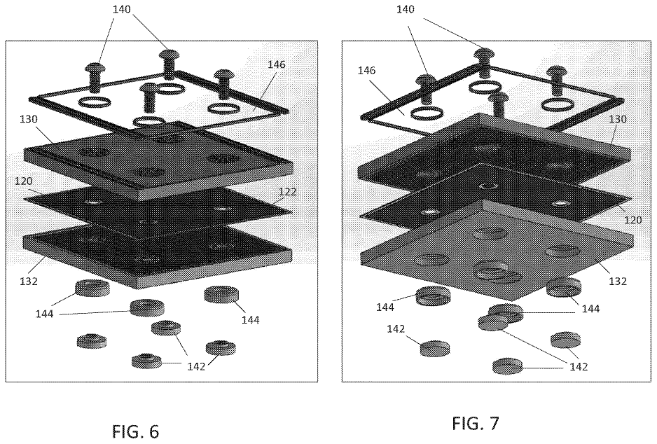

As shown in FIGS. 5-7, each individual fuel cell module 110 is a self-contained electrochemical unit comprising a MEA 120, monopolar plates 130, 132 and an integrated tie-bolt system 140, 142. The MEA 120 features an integrated seal 122 for reactant containment. A cathode monopolar plate 130 and an anode monopolar plate 132 flank the MEA 120. These monopolar plates 130, 132 serve a dual role as both current collectors and primary structural end plates. According to an embodiment, uniform electrical contact pressure (nominally about 150 psi in an embodiment) is maintained across the active area via four internal tie bolts 140. It will be understood that, in other embodiments, there may be more or fewer tie bolts 140. These bolts 140 are sealed and electrically isolated, passing through the cell structure to terminate at the bottom face of the fuel cell assembly 100. In an embodiment, the bolts 140 are sealed by a liquid injection molded gasket 146. As shown in the exploded view of FIGS. 6 and 7, the bolts 140 are held in place by nuts 142, which serve as positive terminals. As shown in FIGS. 6 and 7. Each positive terminal (nut) 142 is surrounded by an electrical isolator 144. The anode monopolar plate 132 serves as the negative terminal. According to an alternative embodiment, the location of the nuts 144 and bolts can be moved from the active area of the MEA 120 to the area outside the seal 122.

The fuel cell assembly 100 features a unique unilateral electrical termination scheme in which both positive terminals (142) and negative terminals (132) are accessible from the bottom face of the fuel cell assembly 100. The positive terminals (represented by the isolated tie-bolt nuts 142) are routed through the negative terminal 132 structure, allowing for simplified “plug-and-play” electrical interfacing on a single plane. Electrical isolation between the 32 fuel cell modules 110 allows for versatile external wiring in series, parallel, or hybrid configurations to meet specific voltage/current requirements.

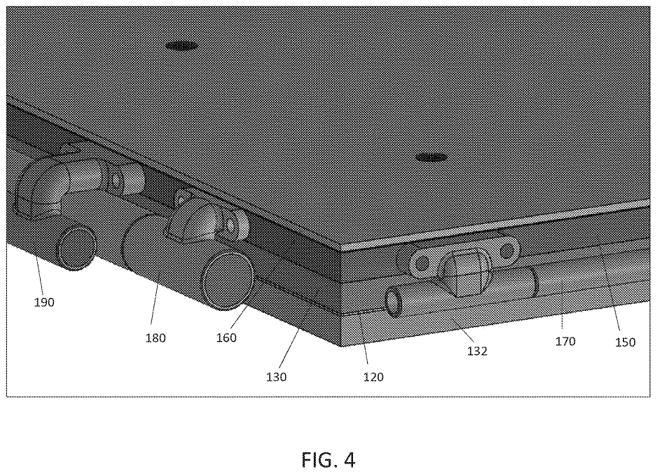

Embodiments of the fuel cell assembly 100 utilizes a layered fluidic routing strategy to manage reactants (hydrogen and air) and thermal media (coolant). In this embodiment, a fluidic connection plate 150 is positioned above the cathode plate 130, and serves as the primary distribution manifold, routing fluids to each of the fuel cell modules 110 via bonded, leak-tight interfaces. As shown in FIG. 5, inlets and outlets for all three fluids are located on the perimeter of the fluid connection plate 150, feeding into the internal fluidic pathways of the fluid connection plate 150. As shown in FIGS. 3-5, a hydrogen manifold 170, air manifold 180, and coolant manifold 190 are connected to these inlets and outlets on the perimeter of the fluid connection plate 150. A thin, topmost laminate 160 over the fluidic connection plate 150 ensures the hermetic integrity of the fluidic pathways. In this embodiment, the fluidic connection plate 150 serves all 32 isolated fuel cell modules 110 simultaneously.

Hydrogen is delivered to the fluidic connection plate 150 via a hydrogen manifold 170. Hydrogen can be generated from compressed natural gas, renewable natural gas, and/or biomass gasification using a steam methane reformer (SMR) 500, which are available from manufacturers, such as Linde Engineering, Airgas, KBR, Lummus Technology, Topsoe, and Honeywell. Alternatively, hydrogen can be delivered from a hydrogen gas pipeline or electrolyzer. A liquid hydrogen tank can be used to supply backup hydrogen. A SMR reacts natural gas (methane, CH₄) with steam (H₂°) over a catalyst at high temperatures (700-1000° C.) to produce hydrogen (H₂) and carbon dioxide (CO₂). The resulting gas mixture is then purified using pressure swing adsorption (PSA), which selectively adsorbs impurities (CO₂, CO, CH₄) to yield high-purity hydrogen (>99.99%).

In the embodiments described herein, the fuel cell power assembly 100 is fueled by hydrogen. It will be understood that, in other embodiments, the fuel cell power assembly 100 can be fueled by other fuels, such as hydrogen-rich gases produced by reforming methanol, natural gas, or liquefied petroleum gas, etc.

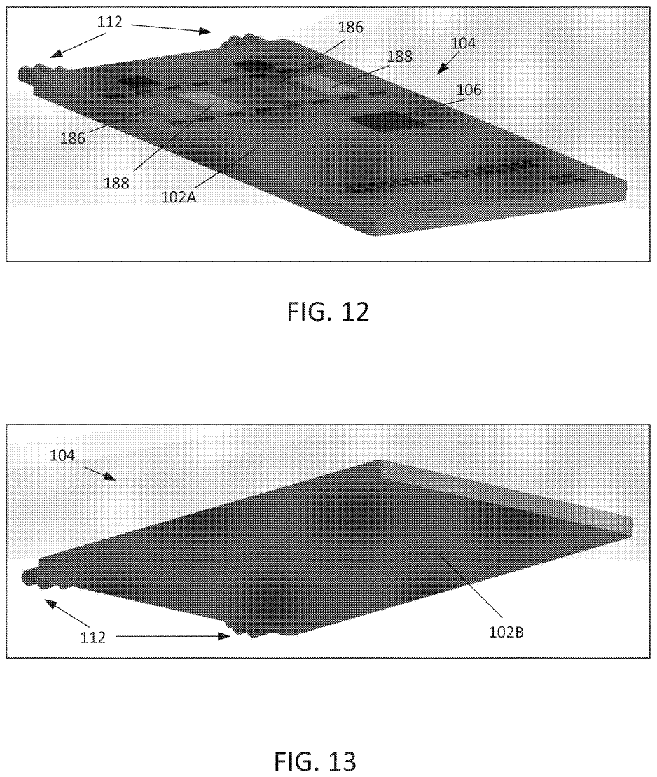

Currently, data centers employ standard size U1 or U2 server rack systems. Every server rack system 300 holds multiple compute trays 200, as shown in FIG. 12. According to an embodiment, each compute tray 200 in a server rack 300 is connected directly to a fuel cell assembly 100, which delivers low-voltage power to the compute tray 200. This direct connection to a power source eliminates losses due to power transmission and power conversion. Currently, data centers are typically powered by electricity from the power grid, which must be transmitted to data centers (with backup power typically provided by battery storage or gas generators). The high-voltage AC grid power must be transmitted and transformed for residential and commercial use, and then further converted to low-voltage DC by a server's power supply unit before being delivered to a GPU, resulting in significant power losses due to power transmission and conversion. A fuel cell assembly 100 directly connected to a compute tray can supply low-voltage power to the compute tray without transmission or conversion losses.

According to an embodiment, the fuel cell assembly 100 in its encapsulating enclosure 102 has a thickness that is less than 0.75 inch. This thin geometry allows the fuel cell assembly 100 to be connected to the bottom of a compute tray 200 and fit into a standard server rack 300, as shown in FIG. 12. Furthermore, the direct low voltage power provided by this arrangement eliminates the need for DC-DC power converters, allowing for additional compute trays 200 in the server rack 300. It also eliminated the need for wiring as it provides direct power through electrical contacts.

It will be understood that power delivery from the electrical grid to a compute tray is a complex, multi-step process that involves transmitting electricity over long distances and converting the power from high-voltage AC power to low-voltage DC power suitable for servers. AC power coming from the electrical grid is transmitted at high-voltage to minimize energy losses over long distances. High-voltage power is typically reduced to medium-voltage power (about 30 kVAC) at a substation for delivery to a data center. Medium-voltage transformers step down the voltage to a suitable building voltage (about 480VAC), which is used for both computing power as well as cooling, lighting, and other utilities. For computing power, a power supply unit (PSU) converts the 480 VAC to 800 VDC, which is fed into the server rack 300. Five DC-DC power converters further convert the voltage down to 1 VDC as follows: 800 VDC to 48 VDC, 48 VDC to 12 VDC, 12 VDC to 5 VDC and 5 VDC to 1 VDC. As noted above, the generation of low-voltage power by a fuel cell assembly 100 and direct delivery of the power (1 VDC) to a compute tray 200 to which the fuel cell assembly 100 is attached eliminates the need to the DC-DC power converters in the server rack 300.

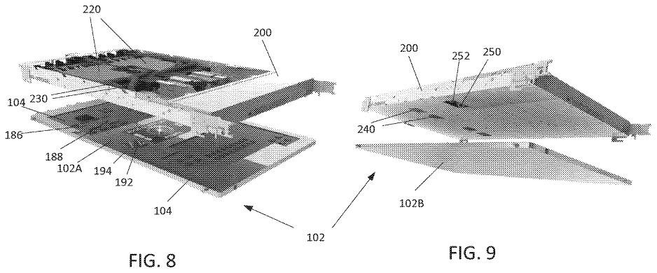

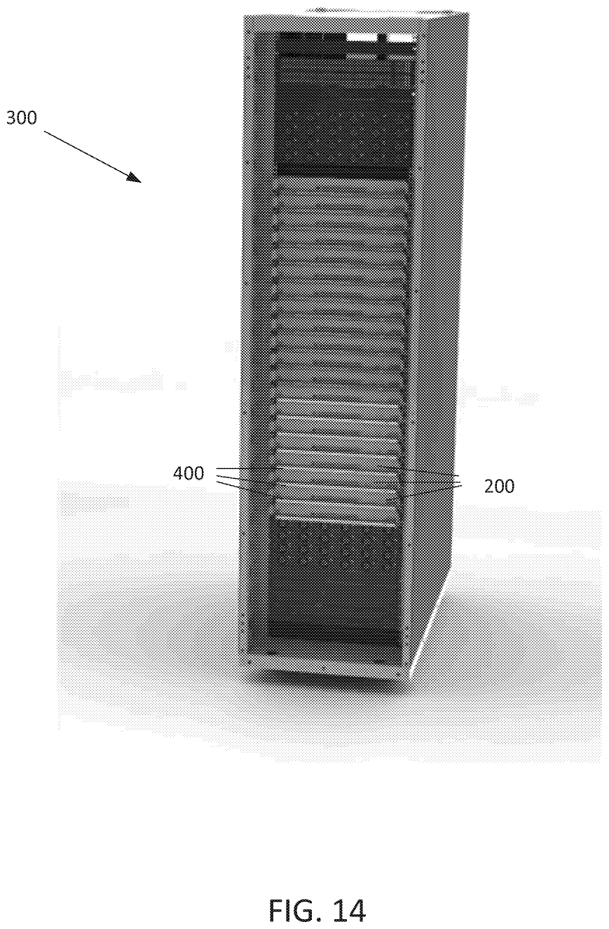

Each compute tray 200 of a server rack 300 can be directly powered by an individual fuel cell assembly 100. A compute tray typically holds 2-4 GPUs along with central processing units (CPUs). It will be understood that some compute tray can hold up to eight or more GPUs. In the embodiment shown in FIGS. 8 and 9, the compute tray 200 holds four GPUs 220. Only two GPUs are shown, but the compute tray 200 holds four GPUs (two stacks of two GPUs). According to an embodiment, the fuel cell assembly 100 provides a high-surface-area, thin-film power source with approximate length and width dimensions of a 1U tray. This “flat-pack” geometry is optimized for integration into structural panels or space-constrained environments where traditional vertical stacks are non-viable. As shown in FIG. 14, a low-voltage fuel cell power system 400 can be connected to the bottom of each compute tray 200 in a rack 300. If one low-voltage fuel cell power system 400 fails, it can be swapped for a new one without affecting the other low-voltage fuel cell power system 400 and compute trays 200 in the rack 300.

Heat is generated when a fuel cell produces electricity. Thus, to maintain desired fuel cell operating temperatures, excess waste heat must be removed. Similarly, the GPUs and CPUs in the compute tray need to be maintained at suitable operating temperatures. The fuel cell assembly 100 has an operating temperature in range of about 50-90° C., whereas the operating temperature of GPUs and CPUs are typically in a range of about 30-90° C. Coolant, such as propylene glycol, ethylene glycol, or water, can be circulated in within a cooling tube 230 in the compute tray 230 to maintain a suitable operating temperature for the GPUs and CPUs. The liquid coolant inlet temperature is typically 30-45° C. The hot coolant discharged from the compute tray 200 can be used as coolant for the fuel cell assembly 100. Thus, additional heat management hardware is not necessary for cooling the fuel cell assembly 100 described herein.

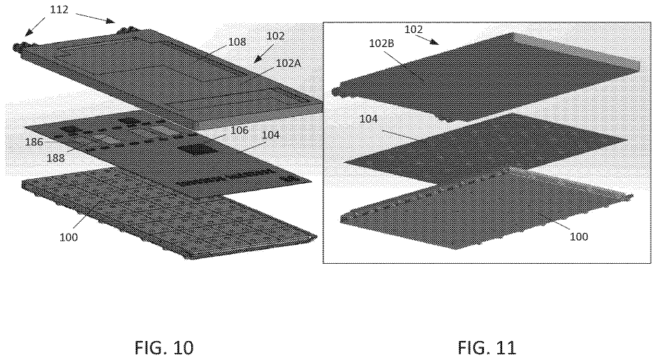

As shown in FIGS. 10 and 11, a printed circuit board (PCB) 104 is positioned between the bottom face of the fuel cell assembly 100 and the top face 102A of the enclosure 102 encapsulating the fuel cell assembly 100 and the PCB 104. Together, the fuel cell assembly, PCB 14, and enclosure 102 form a low-voltage fuel cell power system 400. In the illustrated embodiment, the enclosure 102 is an integrally formed piece and the fuel cell assembly 100 and PCB 104 are inserted into one end (not shown in FIGS. 10 and 11) of the enclosure 102 and that end is then sealed. It will be understood that, in other embodiments, the enclosure 102 may be formed of a top half with openings and a bottom half without openings and these two halves are sealed together after the PCB 104 and fuel cell assembly 100 are positioned inside the enclosure 102 such that the enclosure 102 encapsulates the PCB 104 and fuel cell assembly 100.

The PCB 104 includes a control module 106 for controlling the fuel cell modules 110. FIG. 10 shows the PCB 104 containing one control module 106 in accordance with an embodiment. It will be understood that, in other embodiments, a PCB 104 may contain multiple control modules 106. The PCB 104 has cell contacts on its bottom face to contact the positive and negative terminals 142, 132 on the bottom face of the fuel cell assembly 100. As shown in FIGS. 10 and 11, the bottom face of the PCB 104 contacts the bottom face of the fuel cell assembly 100. The top face of the PCB 104 has positive and negative contact pads 186, 188 for contacting the positive and negative terminals of each GPU 220 on the compute tray 200 to supply power to the GPU.

In the embodiment shown in FIGS. 8-13, the top face 102A of the enclosure 102 is configured to have openings 108 to expose the positive contact pads 186 and negative contact pads 188 on PCB 104 so that the contact pads 186, 188 can contact the positive and negative terminals 240 of the GPUs 220. As shown in FIGS. 8 and 9, the top face 102A also has a fuel cell coolant inlet 192 for receiving hot coolant exiting the compute tray 200 at the compute tray coolant outlet 250. The bottom face 102B of the housing 102 does not have any openings.

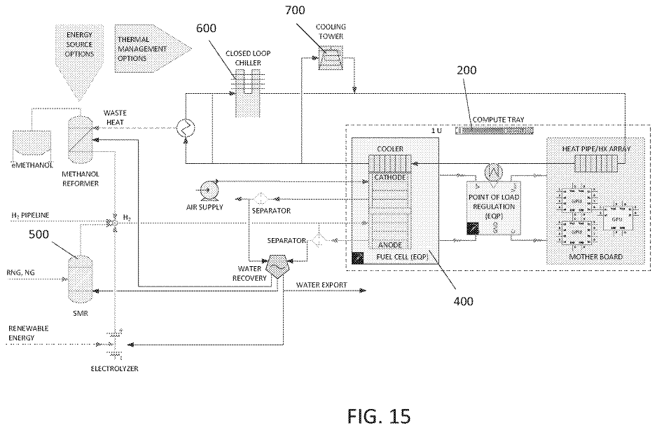

The fuel cell coolant inlet 192 is connected to the coolant manifold 190, which delivers the coolant to all of the fuel cell modules 110 in the fuel cell assembly 100. The hot coolant from the fuel cell assembly 100 can be routed through the fuel cell coolant outlet 194 to the coolant inlet 252 of the compute tray. The coolant inlet 252 of the compute tray 200 is connected to the cooling tube 194 which is connected to the coolant discharge outlet of the compute tray 200. The coolant leaves the compute tray 250 through the coolant discharge outlet (one of the fluidic connections 112) and flows to a closed loop chiller 600 or cooling tower 700 and is recycled back to the compute tray 200 to cool the GPUs and CPUs, as shown in the schematic diagram in FIG. 15. The temperature of the hot coolant exiting the fuel cell assembly 100 is in a range of about 60-85° C. According to an embodiment, the temperature of the hot coolant exiting the fuel cell assembly is about 70-75° C. As shown in FIGS. 8 and 9, the cooling tube 230 of the compute tray 200 is connected to the fuel cell coolant inlet 192 and outlet 194 to deliver hot coolant from the compute tray 200 to the cool the fuel cell assembly 100 and also to receive hot coolant from the fuel cell assembly 100 to discharge the hot coolant from the assembly. It will be understood that the fuel cell coolant inlet 192 is coupled to the compute tray coolant outlet 250 and the fuel cell coolant outlet 194 is coupled to the coolant inlet 252 of the compute tray 200.

As shown in the illustrated embodiment, there are fluidic connections 112 on one end of the enclosure 102. These fluidic connections 112 include the coolant discharge outlet described above for discharging hot coolant from the fuel cell assembly 100 as well as inlets for hydrogen and air. According to an embodiment, hydrogen flows into the fuel cell assembly 100 at a mass flow rate of about 0.25 kg/hr or 42 slpm and air flows into the fuel cell assembly 100 at a mass flow rate of about 302 slpm or 10.8 cfm. Both hydrogen and air are supplied to the fuel cell assembly 100 at a pressure lower than about 30 psig or 200 kPa kPa and at a temperature in a range of approximately 70-80° C. It is understood in the art that increasing the anode and cathode pressure, while providing for high cathode and/or anode inlet humidity in the 80% range can allow a low-temperature proton exchange membrane (LT-PEM) fuel cell to operate at cathode exit temperature at about 80° C. This is advantageous for cooling considerations due to the fact that a lower coolant flow rate can be used, and/or allowing the fuel cell to generate full power at higher ambient temperatures. In this embodiment, the fuel cell assembly 100 outputs DC voltage in a range of about 0.65-0.85 V at a current up to about 6000 A per compute tray 200. The current requirement for an individual compute tray will be dependent on the manufacturer and future improvements. For example, current state of the art NVIDIA Rubin architecture envisions up to eight GPU managed by two CPU per compute tray, and the total compute power (GPU, CPU and memory) is approximately 6,000 A at low voltage less than 2.1 VDC.

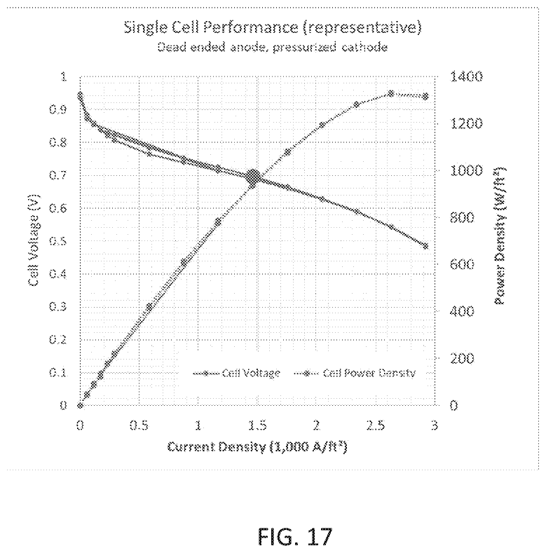

FIG. 17 shows a performance curve of a representative fuel cell. As shown in FIG. 17, the voltage of a fuel cell drops as the current increases. This performance is known in the art as a polarization curve and is a summation of various electrochemical losses in the fuel cell, including anode polarization, cathode polarization, ionic resistance, and electrical resistance. It is also well known in the art that the polarization curve can be modified by varying operating conditions, including humidification, operating temperature, cathode and anode pressures. Additionally, it is well known that the polarization curve will vary over time, with a tendency to reduce performance over time as catalysts, ionomers and other elements of the cell degrade. In summary, it is well understood that a fuel cell is not a stiff voltage source. GPU, CPU, memory, and other AI computer hardware require stiff voltage sources such as 0.8 VDC+/−0.025 V during rapid load transients such as increasing current from 1% duty to 100% duty in less than 1 msec. Therefore, in preferred embodiments, each individual fuel cell module has a dedicated DC/DC converter, or power conditioner, the detailed design of which is not described in this invention, to rapidly manage the output of a given cell to meet the AI computer hardware requirements. These power conditioners must be designed in order to meet the power demands of the AI computer hardware, and also be capable of combining several cells in series or parallel depending on the load demand. Fast acting, actively controlled power conditioners ensure that the AI computer hardware will have the correct voltage and current feed required to stay online. The fuel cell system can include active control over pressure and temperature in order to achieve optimal performance for the AI hardware. However, pressure and temperature control affect fuel cell power in the order of seconds, which is far too slow for the <1 msec required. Hence, active power conditioning circuits are required.

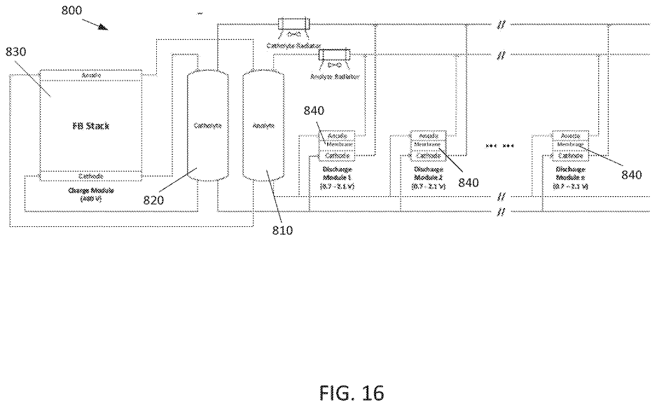

According to an alternative embodiment, a low-voltage flow battery system 800 powers the compute tray 200 rather than a fuel cell assembly. In this embodiment, as shown in FIG. 16, the rechargeable flow battery stores energy in liquid electrolytes, which can be housed in separate anolyte and catholyte tanks 810, 820. The anolyte and catholyte solutions circulate through a flow battery cell stack, where reversible electrochemical reactions occur to store or release energy. The flow battery can be a vanadium redox, zinc-bromine, iron-based, organic, or zinc iodine flow battery.

During charging, electrical energy drives oxidation and reduction reactions in two separate electrolyte streams, converting electrical energy into chemical energy. During discharging, these redox reactions proceed in reverse, generating electricity. Traditionally, charging and discharging occur sequentially in the same redox flow battery (RFB) stack. In this embodiment, these functions are separated into two distinct stacks: a large charging stack 830 and small discharging stacks 840. The large RFB stack 830, which may include hundreds of cells, operates exclusively in charging mode at high input voltages (up to 480 V). The electricity may come from power grids, on-site power plants, or renewable energy sources. The large RFB stack 830 is located outside the server rack, and there may be only one unit for an AI data center. The small RFB stacks 840, which may have just one or two cells, are dedicated to discharging, delivering output voltages in a range of about 0.7-2.1 VDC at currents in a range of about 1000-3000 A to compute trays 200. Both charging and discharging can occur simultaneously, enabling continuous energy flow.

A potential sizing criterion for the individual cell active area may be dependent on its individual control circuit. For example, modern power MOSFET components can efficiently switch and regulate currents up to the 200 A range, and future technology may allow even higher current levels. Therefore, it may make sense to size the individual cell to the amperage rating of the selected MOSFET component, and thereby enable simple and clean electrical design of the control PCB and aggregation of current. An additional sizing criterion for the individual cell could be manufacturing yields. For example, if a few very large cells are required, there may be low manufacturing yields due to the formation of pin-holes or other manufacturing defects.

This embodiment seamlessly integrates energy storage with low-voltage and high-current generation. The anolyte and catholyte of the flow battery can also function as a liquid coolant for the compute tray. By supplying power directly to, it the compute tray, it eliminates the need for traditional power supply units and voltage regulator module and wiring, thereby reducing system cost and complexity while improving energy efficiency. The benefits of flow batteries include long lifespan, scalability, long discharge duration, safety, flexibility, and recyclability.

In view of all of the foregoing, it should be apparent that the present embodiments are illustrative and not restrictive and the invention is not limited to the details given herein, but may be modified within the scope and equivalents of the appended claims.

What is claimed is:

1. A low-voltage fuel cell power system for directly powering a compute tray within a
server rack system, comprising:
a fuel cell assembly electrically coupled to the compute tray to supply power to at least one graphics processing unit in the compute tray, the fuel cell assembly comprising a plurality of fuel cell modules, wherein the fuel cell modules are electrically isolated from one another.

2. The low-voltage fuel cell power system as recited in claim 1, wherein the low-voltage fuel cell power system has a length and width substantially similar to those of the compute tray.

3. The low-voltage fuel cell power system as recited in claim 1, wherein the fuel cell modules are arranged in a single layer.

4. The low-voltage fuel cell power system as recited in claim 2, wherein each of the fuel cell modules comprises:
a membrane electrode assembly;
a cathode monopolar plate on a first side of the membrane electrode assembly; and
an anode monopolar plate on a second side of the membrane electrode assembly.

5. The low-voltage fuel cell power system as recited in claim 4, further comprising a fluidic connection plate fluidically coupled with each of the plurality of fuel cell modules.

6. The low-voltage fuel cell power system as recited in claim 4, wherein each of the fuel cell modules further comprises a plurality of electrically isolated positive tie-bolts routed through the anode monopolar plate.

7. A server rack, comprising:
at least one compute tray comprising at least one graphics processing unit (GPU); and
a low-voltage power source electrically coupled to the at least one compute tray to power the at least one GPU.

8. The server rack as recited in claim 7, wherein the low-voltage power source is a fuel cell power system.

9. The server rack as recited in claim 7, wherein the low-voltage power source is a flow battery system.

10. The server rack as recited in claim 8, wherein the at least one compute tray further comprises a coolant tube fluidically coupled with a coolant manifold in the low-voltage fuel cell power system.

11. The server rack as recited in claim 8, wherein the fuel cell power system comprises a fuel cell assembly comprising a plurality of fuel cell modules, wherein the fuel cell modules are electrically isolated from one another.

12. The server rack as recited in claim 11, wherein the fuel cell modules are arranged in a single layer.

13. The server rack as recited in claim 8, wherein the fuel cell power system has a thickness less than 0.75 inch.

14. The server rack as recited in claim 8, wherein the fuel cell power system has a length and width substantially similar to those of the compute tray.

15. The server rack as recited in claim 9, wherein charging and discharging occur simultaneously in the flow battery system.

16. The server rack as recited in claim 9, wherein the flow battery system comprises a plurality of small redox flow battery stacks that operate only in discharging mode.

17. The server rack as recited in claim 16, wherein each of the small RFB stacks delivers output voltages in a range of about 0.7-2.1 VDC.

18. A low-voltage fuel cell power system for directly powering a compute tray within a
server rack system, comprising:
a fuel cell assembly electrically coupled to the compute tray to supply power to at least one graphics processing unit in the compute tray, the fuel cell assembly comprising a plurality of fuel cell modules arranged in a single layer, wherein the fuel cell modules are electrically isolated from one another.

19. The low-voltage fuel cell power system as recited in claim 18, wherein the low-voltage fuel cell power system has a length and width substantially similar to those of the compute tray.

20. The low-voltage fuel cell power system as recited in claim 18, wherein each of the fuel cell modules comprises:
a membrane electrode assembly;
a cathode monopolar plate on a first side of the membrane electrode assembly; and
an anode monopolar plate on a second side of the membrane electrode assembly.
